(19) United States
(12) Patent Application Publication
(10) Pub. No.: US 2023/0132548 A1
(43) Pub. Date: May 4, 2023

(54) PRE-FLOW OF P-TYPE DOPANT PRECURSOR TO ENABLE THINNER P-GAN LAYERS IN GALLIUM NITRIDE-BASED TRANSISTORS

(71) Applicant: Intel Corporation, Santa Clara, CA (US)

(72) Inventors: Atsunori Tanaka, Hillsboro, OR (US); Sanyam Bajaj, Hillsboro, OR (US); Michael S. Beumer, Portland, OR (US); Robert Ehlert, Portland, OR (US); Gregory P. McNerney, Beaverton, OR (US); Nicholas Minutillo, Beaverton, OR (US); Johann C. Rode, Hillsboro, OR (US); Suresh Vishwanath, Portland, OR (US); Patrick M. Wallace, Hillsboro, OR (US)

(73) Assignee: Intel Corporation, Santa Clara, CA (US)

(21) Appl. No.: 17/519,429

(22) Filed: Nov. 4, 2021

(51) Int. Cl. H01L 29/778; H01L 29/20; H01L 29/66

(52) U.S. Cl. CPC H01L 29/778; H01L 29/2003; H01L 29/66462

(57) ABSTRACT

In one embodiment, a transistor is formed by a process comprising forming a buffer layer on a substrate, the buffer layer comprising a first group III-nitride (III-N) material (e.g., AlGaN), forming a channel layer on the buffer layer, the channel layer comprising a second III-N material (e.g., GaN), forming a polarization layer on the channel layer, the polarization layer comprising a third III-N material (e.g., AlGaN), flowing a p-type dopant precursor compound (e.g., Cp₂Mg) after forming the polarization layer, forming a p-type doped layer (e.g., p-GaN) on the polarization layer, the p-type doped layer comprising a p-type dopant (e.g., Mg) and a fourth III-N material (e.g., GaN), forming a source region adjacent one end of the channel layer, and forming a drain region adjacent another end of the channel layer.

### BACKGROUND

Gallium nitride (GaN) is a group III-V semiconductor that has several advantages over silicon (Si). For example, GaN has a direct and wide band gap, high breakdown field, high electron mobility, thermal stability (e.g., a high melting point), and the ability to form a high-mobility two-dimensional electron gas (2DEG) when deposited on another III-V semiconductor. As a result, GaN transistors are particularly beneficial for high-power and high-frequency electronic devices that operate at high temperatures. Magnesium (Mg)-doped GaN may be used as a gate contact to enable enhancement mode (e-mode) operation in GaN-based high-electron-mobility transistor (HEMT) devices.

### BRIEF DESCRIPTION OF THE DRAWINGS

FIG. 1 illustrates an example GaN-based high-electron-mobility transistor (HEMT) device in accordance with embodiments of the present disclosure.

FIG. 2 illustrates a flow diagram of an example process for fabricating a GaN-based HEMT device in accordance with embodiments of the present disclosure.

FIGS. 3A-3B illustrate plots showing concentrations of Magnesium and Aluminum as a function of depth within HEMT devices fabricated with and without a pre-flow stage as described herein.

FIG. 4 illustrates a chart showing drive currents as a function of threshold voltage for e-mode HEMT devices fabricated with and without a pre-flow stage as described herein.

FIG. 5 illustrates a block diagram of an example electrical device that may include one or more embodiments of the disclosure.

FIG. 6 is a top view of a wafer and dies that may be included in a microelectronic assembly, in accordance with any of the embodiments disclosed herein.

FIG. 7 is a cross-sectional side view of an integrated circuit device that may be included in a microelectronic assembly, in accordance with any of the embodiments disclosed herein.

FIG. 8 is a cross-sectional side view of an integrated circuit device assembly that may include a microelectronic assembly, in accordance with any of the embodiments disclosed herein.

### DETAILED DESCRIPTION

Gallium nitride (GaN) is a group III-V semiconductor that has several advantages over silicon (Si). For example, GaN has a direct and wide band gap, high breakdown field, high electron mobility, thermal stability (e.g., a high melting point), and the ability to form a high-mobility two-dimensional electron gas (2DEG) when deposited on another III-V semiconductor. As a result, GaN transistors are particularly beneficial for high-power and high-frequency electronic devices that operate at high temperatures. In some instances, Magnesium (Mg)-doped GaN may be used as a gate contact to enable enhancement mode (“e-mode”) operation in GaN-based high-electron-mobility transistor (HEMT) devices. The Mg-doped layer may form a p-type doped GaN layer, or “p-GaN” layer. Current e-mode HEMT devices have a relatively thick p-GaN layer, e.g., with layers on the order of ˜5-8× thicker than the polarization layer (which may include Aluminum-doped GaN, AlGAN, InAlN, or other III-N materials), to deplete the 2DEG.

In embodiments of the present disclosure, a pre-flow of Cp₂Mg may be implemented during the fabrication of GaN-based HEMT devices, specifically, prior to the deposition of the p-GaN layer. During the pre-flow of the Cp₂Mg, the fabrication chamber and the wafer surface may be saturated with Cp₂Mg and then highly doped p-GaN is grown immediately against the polarization layer. This may allow for a higher concentration of p-type carriers near the 2DEG in the HEMT device, enabling a thinner pGaN layer (e.g., on the order of ˜1.5× the polarization layer thickness). A thinner p-GaN layer may allow for much better gate control of the HEMT device due to the reduced distance between the gate contact and the channel.

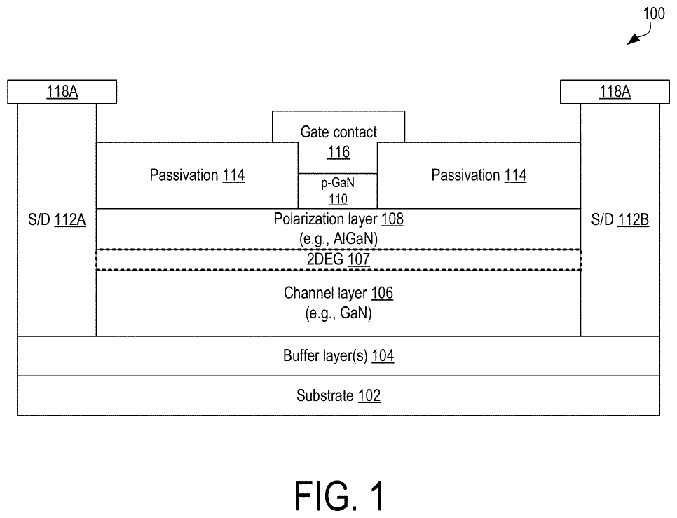

FIG. 1 illustrates an example GaN-based high-electron-mobility transistor (HEMT) device 100 in accordance with embodiments of the present disclosure. The example HEMT device 100 may include additional, fewer, or different components or layers than those shown. Further, it will be understood that the HEMT device 100 shown in FIG. 1 is not necessarily drawn to scale, and proportions of the various layers/components shown may differ from that shown in FIG. 1.

The example HEMT device 100 includes a substrate 102, one or more buffer layers 104 on the substrate, a channel layer 106 on the buffer layers 104, a polarization layer 108 on the channel layer 106, a p-GaN layer 110 on the polarization layer 108, and source/drain regions 112 on either side of the channel and polarization layers. In addition, there is a passivation layer 114 on the polarization layer 108, around/surrounding the p-GaN layer 110, as well as a gate contact 116 on the passivation layer 114 and in contact with the p-GaN layer 110 and source/drain contacts 118 on the source/drain regions 112. Between the channel and polarization layers, there is a two-dimensional electron gas (2DEG) 107 that is formed.

The substrate 102 may be a silicon substrate in certain embodiments, or another suitable substrate material. The buffer layers 104 may include one or more layers of a group III-nitride (III-N) material, such as aluminum gallium nitride (AlGaN). The channel layer 106 may also include a III-N material, such as gallium nitride (GaN). In this manner, the AlGaN buffer layers 104 between the GaN channel layer 106 and the Si substrate 102 may serve as a buffer separating those layers.

The source/drain regions 112 are formed on opposite ends of the channel layer 106 such that they are coupled together via the channel layer 106. Moreover, the source/drain regions 112 may be formed from a III-N material, such as indium gallium nitride (e.g., N+InₓGa₁₋ₓN, where x is between 0 and 0.3 and the dopant is Si) in certain embodiments. The source/drain contacts 118 may be formed on or above-and in contact with-the respective source and drain regions 112. The source and drain contacts 118 may include an electrically conductive material, such as a metal.

The polarization layer 108 may include a III-N material, such as aluminum gallium nitride (AlGaN). The polarization layer 108 may induce the formation of the two-dimensional electron gas (2DEG) 107. For example, when the AlGaN polarization layer 108 is formed on the GaN channel layer 106, the 2DEG 107 forms at or near the interface of the channel layer 106 and the polarization layer 108. The p-GaN layer 110 on the polarization layer 108 may include a III-N material (e.g., gallium nitride (GaN)) and p-type dopants (e.g., magnesium). The p-GaN layer 110 may deplete the 2DEG 107, causing the HEMT device 100 to function as an enhancement mode (e-mode) device rather than a depletion mode (d-mode) device. In embodiments herein, during the fabrication of the device 100, a pre-flow stage involving p-type dopant materials (e.g., Cp₂Mg) may be introduced between the formation of the polarization layer 108 and the formation of the p-GaN layer 110, which may allow for a higher concentration of Mg dopants in the p-GaN layer 110 and thus, a thinner p-GaN layer 110 and thinner overall device 100. For example, in some embodiments, the pre-flow stage may allow for a p-GaN layer 110 having a thickness of less than 20 nm (e.g., 15 nm or 12 nm), whereas current designs may require p-GaN layers with thicknesses on the order of ˜60 nm.

The gate contact 116 may be formed on or above-and in contact with-the the p-GaN layer 110, and may include an electrically conductive material, such as a metal. The passivation layer 114 is formed on or above the polarization layer 108 and around the p-GaN layer 110. The passivation layer 114 may include a dielectric material such as silicon dioxide (SiO₂) or silicon nitride (SiN) and may passivate the surface of the polarization layer 108 (e.g., to protect it from contamination).

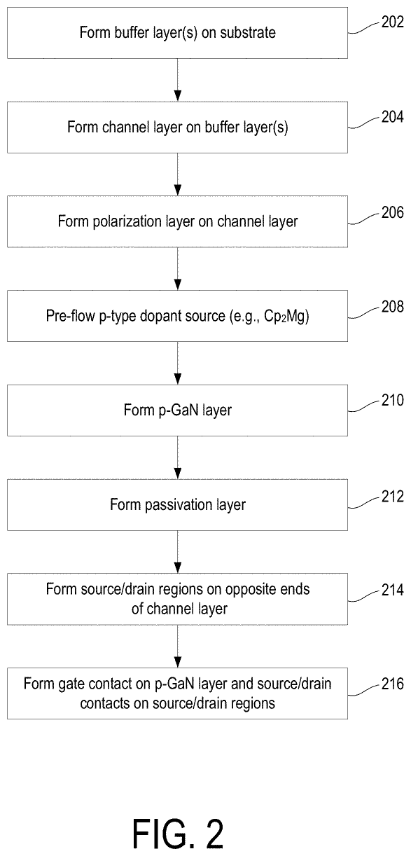

FIG. 2 illustrates a flow diagram of an example process 200 for fabricating a GaN-based high-electron-mobility transistor (HEMT) device (e.g., device 100 of FIG. 1) in accordance with embodiments of the present disclosure. The operations of the process 200 may be performed using any suitable semiconductor fabrication techniques. For example, where not otherwise mentioned below, film deposition—such as depositing layers, filling portions of layers (e.g., removed portions), and filling via openings—may be performed using any suitable deposition techniques, including, for example, chemical vapor deposition (CVD), metalorganic chemical vapor deposition (MOCVD), molecular beam epitaxy (MBE) atomic layer deposition (ALD), and/or physical vapor deposition (PVD). Moreover, patterning and removal—such as interconnect patterning, forming via openings, and shaping—may be performed using any suitable techniques, such as lithography-based patterning/masking and/or etching. Furthermore, additional, fewer, or other operations may be incorporated into the process 200 to fabricate a GaN-based HEMT device in accordance with embodiments of the present disclosure.

At 202, one or more buffer layers (e.g., 104) are formed on a substrate (e.g., 102). In some embodiments, the substrate may be formed from a material that includes silicon (Si), and the buffer layer may be formed from a group III-nitride (III-N) material. The III-N material may include aluminum (Al), gallium (Ga), and/or nitrogen (N), such as aluminum gallium nitride (AlGaN), among other examples.

At 204, a channel layer (e.g., 106) is formed on the buffer layers. In some embodiments, the channel layer may be formed from a III-N material. The III-N material may include gallium (Ga) and/or nitrogen (N), such as gallium nitride (GaN), among other examples.

At 206, a polarization layer (e.g., 108) is formed on the channel layer. In some embodiments, the polarization layer may be formed from a III-N material. The III-N material may include aluminum (Al), gallium (Ga), and/or nitrogen (N), such as aluminum gallium nitride (AlGaN), among other examples. The formation of the polarization layer on the channel layer may form a two-dimensional electron gas (2DEG) (e.g., 107) at or near the interface of the channel layer and the polarization layer. The polarization layer may be formed, in certain embodiments, using chemical vapor deposition techniques (e.g., MOCVD) under the following approximate conditions: 900-1050° C., 20-500 Torr, Aluminum (Al) source flow rate of 0.002-0.3 mol/min, Ga source flow rate of 0.05-5 mol-min, and N source flow rate of 50-2000 mol/min. The flows may last for approximately 30 seconds to 10 minutes.

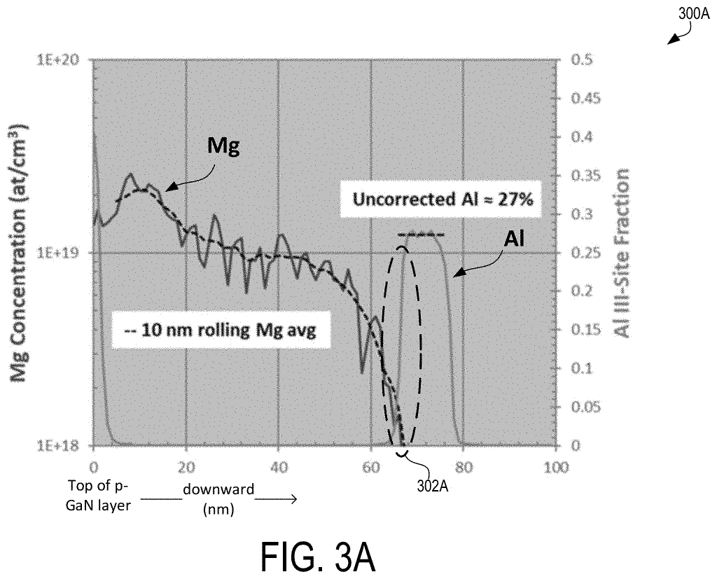

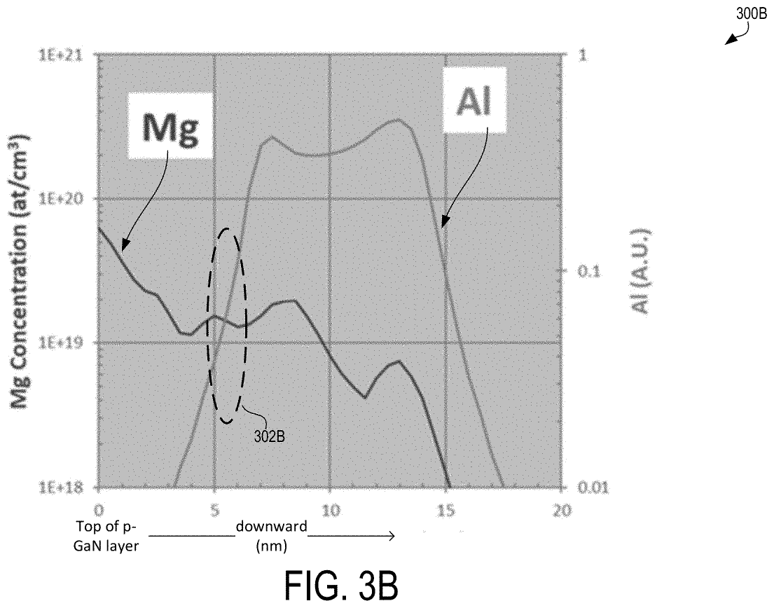

At 208, a p-type dopant pre-flow stage is introduced. In particular, a p-type dopant precursor compound is flowed into the fabrication chamber to saturate the surface of the polarization layer with the p-type dopant (e.g., magnesium (Mg)). The p-type dopant precursor compound may include copernicium (Cp) and/or magnesium (Mg), such as Bis(cyclopentadienyl)magnesium (Cp₂Mg) (where the Mg is the p-type dopant), among other examples. The p-type dopant precursor compound may be introduced, in certain embodiments, using chemical vapor deposition techniques (e.g., MOCVD) under the following approximate conditions: 900-1050° C., 20-500 Torr, and a flow rate of 0.0005-0.005 mol/min. The flow of the p-type dopant precursor compound (e.g., Cp₂Mg) may last for approximately 2-5 min. In the resulting HEMT device, the pre-flow stage may result in the p-type dopant being present in the polarization layer, e.g., as shown in FIG. 3B and described below.

At 210, a p-GaN layer (e.g., 110) is formed on the polarization layer. The p-GaN layer may be formed, in certain embodiments, using chemical vapor deposition techniques (e.g., MOCVD) under the following approximate conditions: 900-1050° C., 20-500 Torr, Mg source flow rate of 0.0005-0.005 mol/min, Ga source flow rate of 0.05-5 mol-min, and N source flow rate of 50-2000 mol/min. The flows may last for approximately 30 seconds to 10 minutes.

At 212, a passivation layer (e.g., 114) is formed on the polarization layer. In some embodiments, the passivation layer may be formed from a material that includes silicon (Si), oxygen (O), and/or nitrogen (N), such as silicon dioxide (SiO₂) or silicon nitride (SiN), among other examples.

At 214, source/drain regions (e.g., 112) are formed on opposite ends of the channel layer. For example, a first source/drain region may be formed adjacent to one end of the channel layer, and a second source/drain region may be formed adjacent to another (e.g., opposite) end of the channel layer (e.g., as shown in FIG. 1) to couple the respective source/drain regions via the channel layer. In some embodiments, the source/drain regions may be formed from a material that includes indium (In), gallium (Ga), and/or nitrogen (N), such as indium gallium nitride (e.g., N+InₓGa₁₋ₓN, where x is between 0 and 0.3 and the dopant is Si), among other examples.

At 216, a gate contact (e.g., 116) is formed on the p-GaN layer and source/drain contacts (e.g., 118) are formed on the source/drain regions. In some embodiments, the gate contact and source/drain contacts may be formed from an electrically conductive material such as a metal.

FIGS. 3A-3B illustrate plots 300 showing concentrations of Magnesium and Aluminum as a function of depth within HEMT devices fabricated with and without a Cp₂Mg pre-flow stage as described herein, respectively. In particular, FIG. 3A illustrates the concentrations for an HEMT device fabricated without a Cp₂Mg pre-flow stage between the formation of the polarization and p-GaN layers, and FIG. 3B illustrates the concentrations for an HEMT device fabricated with a Cp₂Mg pre-flow stage between the formation of the polarization and p-GaN layers as described herein. In the plot 300A of FIG. 3A, there is an average Mg concentration of ˜1×10¹⁹ cm⁻³ throughout the p-GaN layer, whereas in the plot 300B of FIG. 3B (the device in which the Cp₂Mg pre-flow stage is introduced), there is an average Mg concentration of ˜1-2×10¹⁹ cm⁻³. Further, one benefit afforded by the pre-flow of the Cp₂Mg before the p-GaN growth can be seen in the profiles of the curves in each plot. For instance, in FIG. 3A, the Mg concentration drops-off sharply around 5-10 nm above the polarization layer interface 302A (i.e., where the Al concentration curve rises sharply), while in FIG. 3B, the Mg concentration remains relatively flat past the polarization layer interface 302B. This means that there is a higher Mg concentration closer to the 2DEG in the device of FIG. 3B, which may enable the depletion of the 2DEG with a thinner pGaN layer (as seen in the thickness of ˜65 nm in FIG. 3A vs. ˜5 nm in FIG. 3B, since the 0 of the x-axis represents the top of the p-GaN layer in each plot).

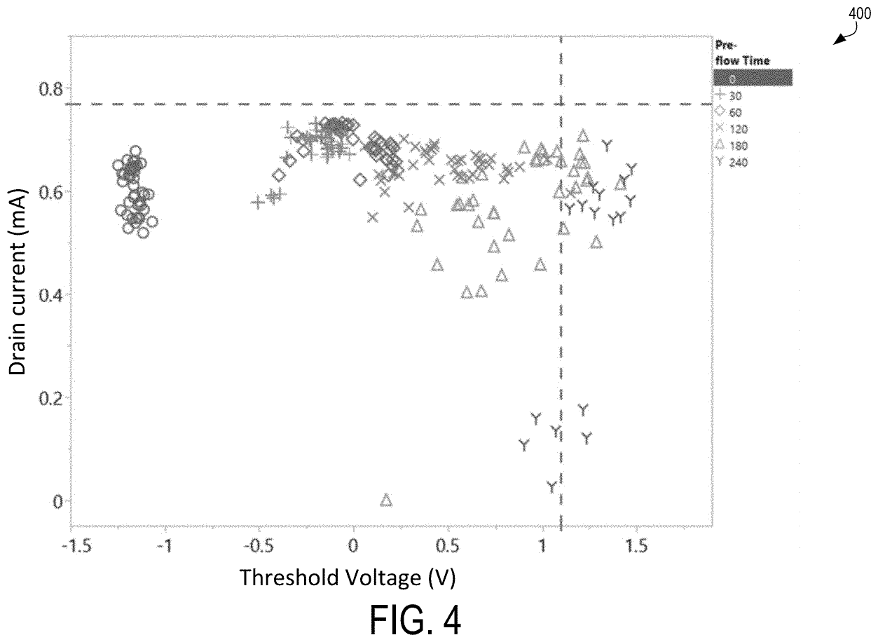

FIG. 4 illustrates a chart 400 showing drive currents as a function of threshold voltage for e-mode HEMT devices fabricated with and without a pre-flow stage as described herein. In the example chart 400, each plot point represents an HEMT device that includes a 12 nm p-GaN layer with various Cp2Mg pre-flow times and a constant Cp2Mg flow rate (150 sccm). The various plot point shapes represent different amounts of time for the Cp₂Mg pre-flow described above, with circles representing 0s of pre-flow (i.e., no pre-flow stage), plus signs representing 30 seconds of Cp₂Mg pre-flow, diamonds representing 60 seconds of Cp₂Mg pre-flow, Xs representing 120 seconds of Cp₂Mg pre-flow, triangles representing 180 seconds of Cp₂Mg pre-flow, and Ys representing 240 seconds of Cp₂Mg pre-flow. As shown, with no Cp₂Mg pre-flow, a 12 nm layer is unable to deplete the 2DEG enough for the device to be normally off, and is far from hitting the example threshold voltage target represented by the vertical dashed line. However, it is also shown that HEMT devices with a Cp₂Mg pre-flow of 120 s or greater produce a normally off device with sufficient threshold voltage and no degradation with respect to the drive current (which may have been assumed due to Mg diffusion into the polarization layer as shown in FIG. 3B).

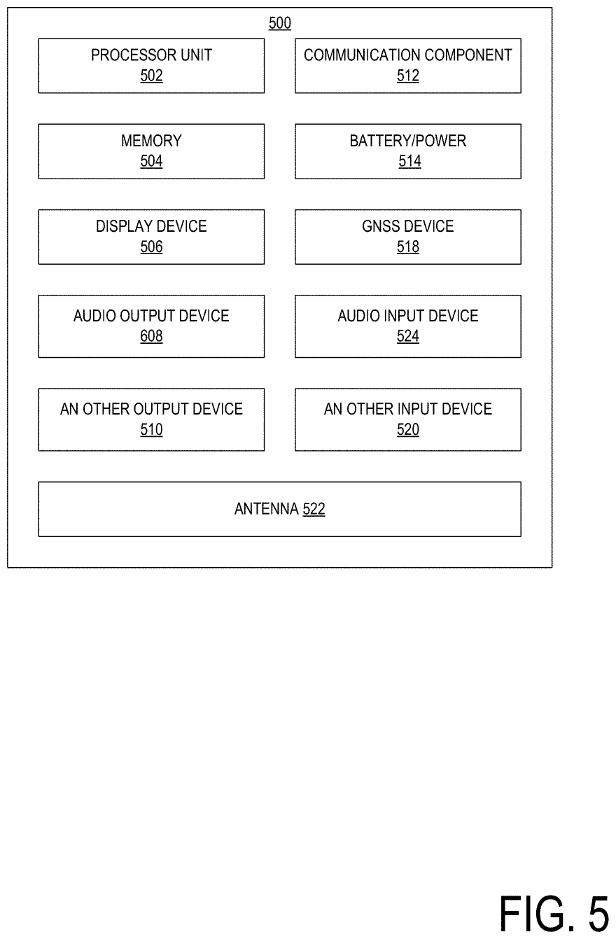

FIG. 5 illustrates a block diagram of an example electrical device 500 that may include one or more of the embodiments disclosed herein. For example, any suitable ones of the components of the electrical device 500—such as processor units 502, memory 504, communication components 512 (e.g., network interface controllers, RF front-end circuits)—may include one or more of the group III-nitride (III-N) transistors described herein (e.g., GaN-based HEMT devices fabricated using a Cp₂Mg pre-flow stage as described above). A number of components are illustrated in FIG. 5 as included in the electrical device 500, but any one or more of these components may be omitted or duplicated, as suitable for the application. In some embodiments, some or all of the components included in the electrical device 500 may be attached to one or more motherboards mainboards, or system boards. In some embodiments, one or more of these components are fabricated onto a single system-on-a-chip (SoC) die.

Additionally, in various embodiments, the electrical device 500 may not include one or more of the components illustrated in FIG. 5, but the electrical device 500 may include interface circuitry for coupling to the one or more components. For example, the electrical device 500 may not include a display device 506, but may include display device interface circuitry (e.g., a connector and driver circuitry) to which a display device 506 may be coupled. In another set of examples, the electrical device 500 may not include an audio input device 524 or an audio output device 508, but may include audio input or output device interface circuitry (e.g., connectors and supporting circuitry) to which an audio input device 524 or audio output device 508 may be coupled.

The electrical device 500 may include one or more processor units 502 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 502 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 500 may include a memory 504, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 504 may include memory that is located on the same integrated circuit die as the processor unit 502. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 500 can comprise one or more processor units 502 that are heterogeneous or asymmetric to another processor unit 502 in the electrical device 500. There can be a variety of differences between the processing units 502 in a system in terms of a spectrum of metrics of merit including architectural, microarchitectural, thermal, power consumption characteristics, and the like. These differences can effectively manifest themselves as asymmetry and heterogeneity among the processor units 502 in the electrical device 500.

In some embodiments, the electrical device 500 may include a communication component 512 (e.g., one or more communication components). For example, the communication component 512 can manage wireless communications for the transfer of data to and from the electrical device 500. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 512 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16—2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 512 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 512 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 512 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 512 may operate in accordance with other wireless protocols in other embodiments. In some embodiments, the communication component 512 may include a radio-frequency (RF) front-end circuit. The electrical device 500 may include an antenna 522 to facilitate wireless communications and/or to receive other wireless communications (such as AM or FM radio transmissions).

In some embodiments, the communication component 512 may manage wired communications, such as electrical, optical, or any other suitable communication protocols (e.g., IEEE 802.3 Ethernet standards). As noted above, the communication component 512 may include multiple communication components. For instance, a first communication component 512 may be dedicated to shorter-range wireless communications such as Wi-Fi or Bluetooth, and a second communication component 512 may be dedicated to longer-range wireless communications such as global positioning system (GPS), EDGE, GPRS, CDMA, WiMAX, LTE, EV-DO, or others. In some embodiments, a first communication component 512 may be dedicated to wireless communications, and a second communication component 512 may be dedicated to wired communications. In some embodiments, the communication component 512 may include a network interface controller.

The electrical device 500 may include battery/power circuitry 514. The battery/power circuitry 514 may include one or more energy storage devices (e.g., batteries or capacitors) and/or circuitry for coupling components of the electrical device 500 to an energy source separate from the electrical device 500 (e.g., AC line power).

The electrical device 500 may include a display device 506 (or corresponding interface circuitry, as discussed above). The display device 506 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 500 may include an audio output device 508 (or corresponding interface circuitry, as discussed above). The audio output device 508 may include any embedded or wired or wirelessly connected external device that generates an audible indicator, such speakers, headsets, or earbuds.

The electrical device 500 may include an audio input device 524 (or corresponding interface circuitry, as discussed above). The audio input device 524 may include any embedded or wired or wirelessly connected device that generates a signal representative of a sound, such as microphones, microphone arrays, or digital instruments (e.g., instruments having a musical instrument digital interface (MIDI) output). The electrical device 500 may include a Global Navigation Satellite System (GNSS) device 518 (or corresponding interface circuitry, as discussed above), such as a Global Positioning System (GPS) device. The GNSS device 518 may be in communication with a satellite-based system and may determine a geolocation of the electrical device 500 based on information received from one or more GNSS satellites, as known in the art.

The electrical device 500 may include other output device(s) 510 (or corresponding interface circuitry, as discussed above). Examples of the other output device(s) 510 may include an audio codec, a video codec, a printer, a wired or wireless transmitter for providing information to other devices, or an additional storage device.

The electrical device 500 may include other input device(s) 520 (or corresponding interface circuitry, as discussed above). Examples of the other input device(s) 520 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 500 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 500 may be any other electronic device that processes data. In some embodiments, the electrical device 500 may comprise multiple discrete physical components. Given the range of devices that the electrical device 500 can be manifested as in various embodiments, in some embodiments, the electrical device 500 can be referred to as a computing device or a computing system.

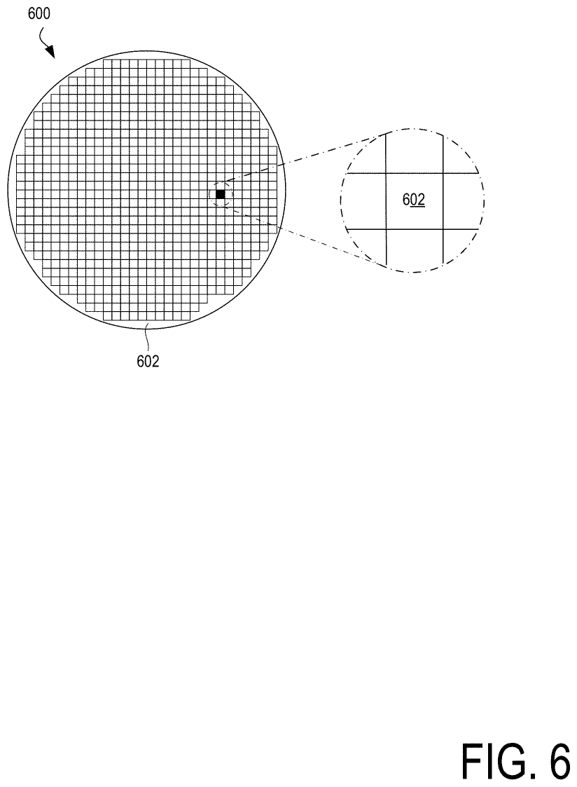

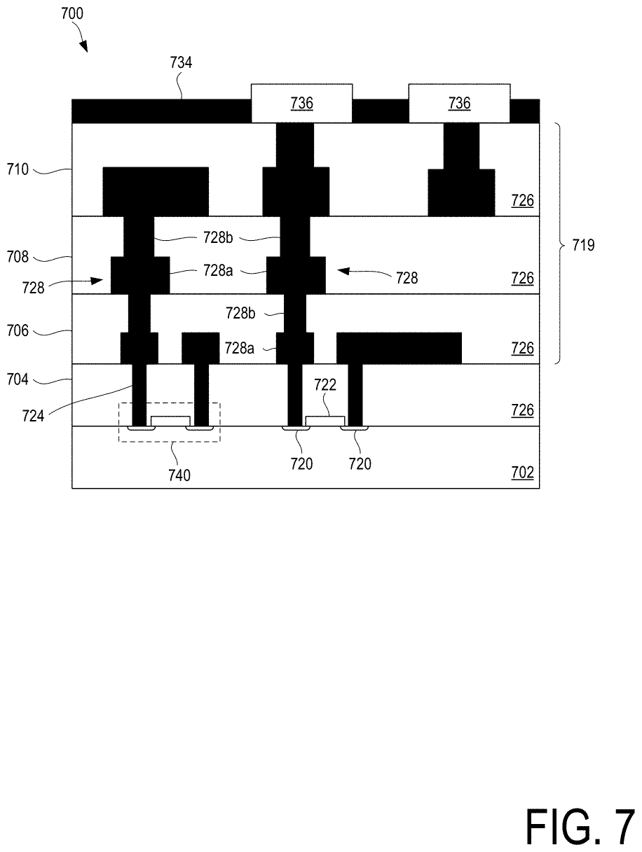

FIG. 6 is a top view of a wafer 600 and dies 602 that may be included in any of the embodiments disclosed herein. The wafer 600 may be composed of semiconductor material and may include one or more dies 602 having integrated circuit structures formed on a surface of the wafer 600. The individual dies 602 may be a repeating unit of an integrated circuit product that includes any suitable integrated circuit. After the fabrication of the semiconductor product is complete, the wafer 600 may undergo a singulation process in which the dies 602 are separated from one another to provide discrete “chips” of the integrated circuit product. The die 602 may be any of the dies disclosed herein. The die 602 may include one or more transistors (e.g., a GaN-based HEMT device, e.g., 100, fabricated using a Cp₂Mg pre-flow stage as described with respect to FIG. 2 and/or the transistors 740 of FIG. 7), supporting circuitry to route electrical signals to the transistors, passive components (e.g., signal traces, resistors, capacitors, or inductors), and/or any other integrated circuit components. In some embodiments, the wafer 600 or the die 602 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 602. For example, a memory array formed by multiple memory devices may be formed on a same die 602 as a processor unit (e.g., the processor unit 502 of FIG. 5) or other logic that is configured to store information in the memory devices or execute instructions stored in the memory array. Various ones of the microelectronic assemblies disclosed herein may be manufactured using a die-to-wafer assembly technique in which some dies are attached to a wafer 600 that include others of the dies, and the wafer 600 is subsequently singulated.

FIG. 7 is a cross-sectional side view of an integrated circuit device 700 that may be included in any of the embodiments disclosed herein (e.g., in any of the dies). One or more of the integrated circuit devices 700 may be included in one or more dies 602 (FIG. 6). The integrated circuit device 700 may be formed on a die substrate 702 (e.g., the wafer 600 of FIG. 6) and may be included in a die (e.g., the die 602 of FIG. 6). The die substrate 702 may be a semiconductor substrate composed of semiconductor material systems including, for example, n-type or p-type materials systems (or a combination of both). The die substrate 702 may include, for example, a crystalline substrate formed using a bulk silicon or a silicon-on-insulator (SOI) substructure. In some embodiments, the die substrate 702 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 702. Although a few examples of materials from which the die substrate 702 may be formed are described here, any material that may serve as a foundation for an integrated circuit device 700 may be used. The die substrate 702 may be part of a singulated die (e.g., the dies 602 of FIG. 6) or a wafer (e.g., the wafer 600 of FIG. 6).

The integrated circuit device 700 may include one or more device layers 704 disposed on the die substrate 702. The device layer 704 may include features of one or more transistors 740 (e.g., metal oxide semiconductor field-effect transistors (MOSFETs)) formed on the die substrate 702. The transistors 740 may include, for example, one or more source and/or drain (S/D) regions 720, a gate 722 to control current flow between the S/D regions 720, and one or more S/D contacts 724 to route electrical signals to/from the S/D regions 720. The transistors 740 may include additional features not depicted for the sake of clarity, such as device isolation regions, gate contacts, and the like. The transistors 740 are not limited to the type and configuration depicted in FIG. 7 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 7, a transistor 740 may include a gate 722 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 740 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 740 along the source-channel-drain direction, the gate electrode may consist of a U-shaped structure that includes a bottom portion substantially parallel to the surface of the die substrate 702 and two sidewall portions that are substantially perpendicular to the top surface of the die substrate 702. In other embodiments, at least one of the metal layers that form the gate electrode may simply be a planar layer that is substantially parallel to the top surface of the die substrate 702 and does not include sidewall portions substantially perpendicular to the top surface of the die substrate 702. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 720 may be formed within the die substrate 702 adjacent to the gate 722 of individual transistors 740. The S/D regions 720 may be formed using an implantation/diffusion process or an etching/deposition process, for example. In the former process, dopants such as boron, aluminum, antimony, phosphorous, or arsenic may be ion-implanted into the die substrate 702 to form the S/D regions 720. An annealing process that activates the dopants and causes them to diffuse farther into the die substrate 702 may follow the ion-implantation process. In the latter process, the die substrate 702 may first be etched to form recesses at the locations of the S/D regions 720. An epitaxial deposition process may then be carried out to fill the recesses with material that is used to fabricate the S/D regions 720. In some implementations, the S/D regions 720 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 720 may be formed using one or more alternate semiconductor materials such as germanium or a group III-V material or alloy. In further embodiments, one or more layers of metal and/or metal alloys may be used to form the S/D regions 720.

Electrical signals, such as power and/or input/output (I/O) signals, may be routed to and/or from the devices (e.g., transistors 740) of the device layer 704 through one or more interconnect layers disposed on the device layer 704 (illustrated in FIG. 7 as interconnect layers 706-710). For example, electrically conductive features of the device layer 704 (e.g., the gate 722 and the S/D contacts 724) may be electrically coupled with the interconnect structures 728 of the interconnect layers 706-710. The one or more interconnect layers 706-710 may form a metallization stack (also referred to as an “ILD stack”) 719 of the integrated circuit device 700.

The interconnect structures 728 may be arranged within the interconnect layers 706-710 to route electrical signals according to a wide variety of designs; in particular, the arrangement is not limited to the particular configuration of interconnect structures 728 depicted in FIG. 7. Although a particular number of interconnect layers 706-710 is depicted in FIG. 7, embodiments of the present disclosure include integrated circuit devices having more or fewer interconnect layers than depicted.

In some embodiments, the interconnect structures 728 may include lines 728a and/or vias 728b filled with an electrically conductive material such as a metal. The lines 728a may be arranged to route electrical signals in a direction of a plane that is substantially parallel with a surface of the die substrate 702 upon which the device layer 704 is formed. For example, the lines 728a may route electrical signals in a direction in and out of the page and/or in a direction across the page from the perspective of FIG. 7. The vias 728b may be arranged to route electrical signals in a direction of a plane that is substantially perpendicular to the surface of the die substrate 702 upon which the device layer 704 is formed. In some embodiments, the vias 728b may electrically couple lines 728a of different interconnect layers 706-710 together.

The interconnect layers 706-710 may include a dielectric material 726 disposed between the interconnect structures 728, as shown in FIG. 7. In some embodiments, dielectric material 726 disposed between the interconnect structures 728 in different ones of the interconnect layers 706-710 may have different compositions; in other embodiments, the composition of the dielectric material 726 between different interconnect layers 706-710 may be the same. The device layer 704 may include a dielectric material 726 disposed between the transistors 740 and a bottom layer of the metallization stack as well. The dielectric material 726 included in the device layer 704 may have a different composition than the dielectric material 726 included in the interconnect layers 706-710; in other embodiments, the composition of the dielectric material 726 in the device layer 704 may be the same as a dielectric material 726 included in any one of the interconnect layers 706-710.

A first interconnect layer 706 (referred to as Metal 1 or “M1”) may be formed directly on the device layer 704. In some embodiments, the first interconnect layer 706 may include lines 728a and/or vias 728b, as shown. The lines 728a of the first interconnect layer 706 may be coupled with contacts (e.g., the S/D contacts 724) of the device layer 704. The vias 728b of the first interconnect layer 706 may be coupled with the lines 728a of a second interconnect layer 708.

The second interconnect layer 708 (referred to as Metal 2 or “M2”) may be formed directly on the first interconnect layer 706. In some embodiments, the second interconnect layer 708 may include via 728b to couple the lines 728 of the second interconnect layer 708 with the lines 728a of a third interconnect layer 710. Although the lines 728a and the vias 728b are structurally delineated with a line within individual interconnect layers for the sake of clarity, the lines 728a and the vias 728b may be structurally and/or materially contiguous (e.g., simultaneously filled during a dual-damascene process) in some embodiments.

The third interconnect layer 710 (referred to as Metal 3 or “M3”) (and additional interconnect layers, as desired) may be formed in succession on the second interconnect layer 708 according to similar techniques and configurations described in connection with the second interconnect layer 708 or the first interconnect layer 706. In some embodiments, the interconnect layers that are “higher up” in the metallization stack 719 in the integrated circuit device 700 (i.e., farther away from the device layer 704) may be thicker that the interconnect layers that are lower in the metallization stack 719, with lines 728a and vias 728b in the higher interconnect layers being thicker than those in the lower interconnect layers.

The integrated circuit device 700 may include a solder resist material 734 (e.g., polyimide or similar material) and one or more conductive contacts 736 formed on the interconnect layers 706-710. In FIG. 7, the conductive contacts 736 are illustrated as taking the form of bond pads. The conductive contacts 736 may be electrically coupled with the interconnect structures 728 and configured to route the electrical signals of the transistor(s) 740 to external devices. For example, solder bonds may be formed on the one or more conductive contacts 736 to mechanically and/or electrically couple an integrated circuit die including the integrated circuit device 700 with another component (e.g., a printed circuit board). The integrated circuit device 700 may include additional or alternate structures to route the electrical signals from the interconnect layers 706-710; for example, the conductive contacts 736 may include other analogous features (e.g., posts) that route the electrical signals to external components. The conductive contacts 736 may serve as any of the conductive contacts described throughout this disclosure.

In some embodiments in which the integrated circuit device 700 is a double-sided die, the integrated circuit device 700 may include another metallization stack (not shown) on the opposite side of the device layer(s) 704. This metallization stack may include multiple interconnect layers as discussed above with reference to the interconnect layers 706-710, to provide conductive pathways (e.g., including conductive lines and vias) between the device layer(s) 704 and additional conductive contacts (not shown) on the opposite side of the integrated circuit device 700 from the conductive contacts 736. These additional conductive contacts may serve as any of the conductive contacts described throughout this disclosure.

In other embodiments in which the integrated circuit device 700 is a double-sided die, the integrated circuit device 700 may include one or more through silicon vias (TSVs) through the die substrate 702; these TSVs may make contact with the device layer(s) 704, and may provide conductive pathways between the device layer(s) 704 and additional conductive contacts (not shown) on the opposite side of the integrated circuit device 700 from the conductive contacts 736. These additional conductive contacts may serve as any of the conductive contacts described throughout this disclosure. In some embodiments, TSVs extending through the substrate can be used for routing power and ground signals from conductive contacts on the opposite side of the integrated circuit device 700 from the conductive contacts 736 to the transistors 740 and any other components integrated into the die 700, and the metallization stack 719 can be used to route I/O signals from the conductive contacts 736 to transistors 740 and any other components integrated into the die 700.

Multiple integrated circuit devices 700 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

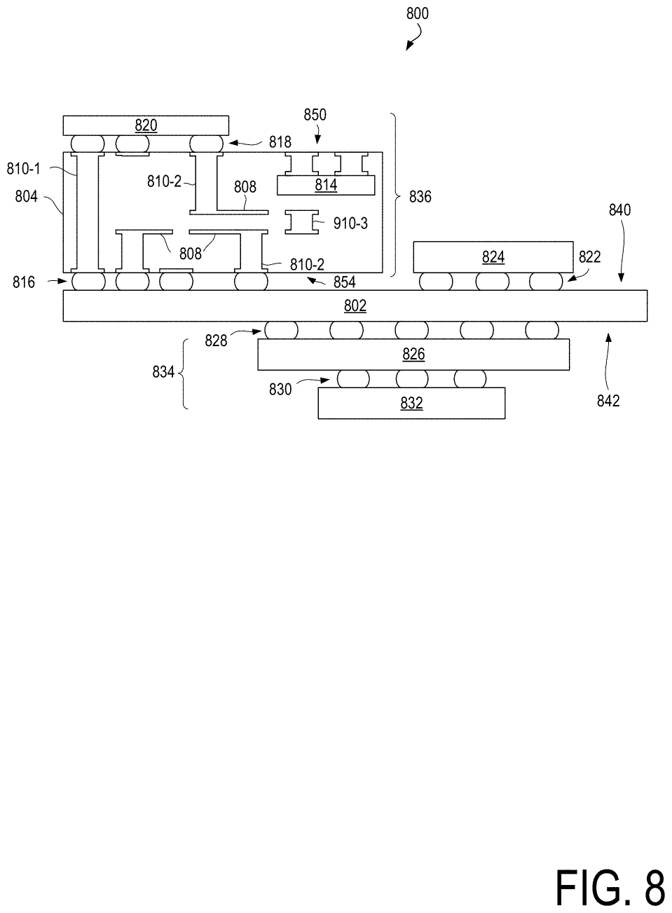

FIG. 8 is a cross-sectional side view of an integrated circuit device assembly 800 that may include any of the embodiments disclosed herein. In some embodiments, the integrated circuit device assembly 800 may be a microelectronic assembly. The integrated circuit device assembly 800 includes a number of components disposed on a circuit board 802 (which may be a motherboard, system board, mainboard, etc.). The integrated circuit device assembly 800 includes components disposed on a first face 840 of the circuit board 802 and an opposing second face 842 of the circuit board 802; generally, components may be disposed on one or both faces 840 and 842. Any of the integrated circuit components discussed below with reference to the integrated circuit device assembly 800 may take the form of any suitable ones of the embodiments of the microelectronic assemblies 100 disclosed herein.

In some embodiments, the circuit board 802 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 802. In other embodiments, the circuit board 802 may be a non-PCB substrate. The integrated circuit device assembly 800 illustrated in FIG. 8 includes a package-on-interposer structure 836 coupled to the first face 840 of the circuit board 802 by coupling components 816. The coupling components 816 may electrically and mechanically couple the package-on-interposer structure 836 to the circuit board 802, and may include solder balls (as shown in FIG. 8), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 816 may serve as the coupling components illustrated or described for any of the substrate assembly or substrate assembly components described herein, as appropriate.

The package-on-interposer structure 836 may include an integrated circuit component 820 coupled to an interposer 804 by coupling components 818. The coupling components 818 may take any suitable form for the application, such as the forms discussed above with reference to the coupling components 816. Although a single integrated circuit component 820 is shown in FIG. 8, multiple integrated circuit components may be coupled to the interposer 804; indeed, additional interposers may be coupled to the interposer 804. The interposer 804 may provide an intervening substrate used to bridge the circuit board 802 and the integrated circuit component 820.

The integrated circuit component 820 may be a packaged or unpacked integrated circuit product that includes one or more integrated circuit dies (e.g., the die 602 of FIG. 6, the integrated circuit device 700 of FIG. 7) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 820, a single monolithic integrated circuit die comprises solder bumps attached to contacts on the die. The solder bumps allow the die to be directly attached to the interposer 804. The integrated circuit component 820 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 820 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 820 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 820 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 804 may spread connections to a wider pitch or reroute a connection to a different connection. For example, the interposer 804 may couple the integrated circuit component 820 to a set of ball grid array (B GA) conductive contacts of the coupling components 816 for coupling to the circuit board 802. In the embodiment illustrated in FIG. 8, the integrated circuit component 820 and the circuit board 802 are attached to opposing sides of the interposer 804; in other embodiments, the integrated circuit component 820 and the circuit board 802 may be attached to a same side of the interposer 804. In some embodiments, three or more components may be interconnected by way of the interposer 804.

In some embodiments, the interposer 804 may be formed as a PCB, including multiple metal layers separated from one another by layers of dielectric material and interconnected by electrically conductive vias. In some embodiments, the interposer 804 may be formed of an epoxy resin, a fiberglass-reinforced epoxy resin, an epoxy resin with inorganic fillers, a ceramic material, or a polymer material such as polyimide. In some embodiments, the interposer 804 may be formed of alternate rigid or flexible materials that may include the same materials described above for use in a semiconductor substrate, such as silicon, germanium, and other group III-V and group IV materials. The interposer 804 may include metal interconnects 808 and vias 810, including but not limited to through hole vias 810-1 (that extend from a first face 850 of the interposer 804 to a second face 854 of the interposer 804), blind vias 810-2 (that extend from the first or second faces 850 or 854 of the interposer 804 to an internal metal layer), and buried vias 810-3 (that connect internal metal layers).

In some embodiments, the interposer 804 can comprise a silicon interposer. Through silicon vias (TSV) extending through the silicon interposer can connect connections on a first face of a silicon interposer to an opposing second face of the silicon interposer. In some embodiments, an interposer 804 comprising a silicon interposer can further comprise one or more routing layers to route connections on a first face of the interposer 804 to an opposing second face of the interposer 804.

The interposer 804 may further include embedded devices 814, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 804. The package-on-interposer structure 836 may take the form of any of the package-on-interposer structures known in the art. In embodiments where the interposer is a non-printed circuit board

The integrated circuit device assembly 800 may include an integrated circuit component 824 coupled to the first face 840 of the circuit board 802 by coupling components 822. The coupling components 822 may take the form of any of the embodiments discussed above with reference to the coupling components 816, and the integrated circuit component 824 may take the form of any of the embodiments discussed above with reference to the integrated circuit component 820.

The integrated circuit device assembly 800 illustrated in FIG. 8 includes a package-on-package structure 834 coupled to the second face 842 of the circuit board 802 by coupling components 828. The package-on-package structure 834 may include an integrated circuit component 826 and an integrated circuit component 832 coupled together by coupling components 830 such that the integrated circuit component 826 is disposed between the circuit board 802 and the integrated circuit component 832. The coupling components 828 and 830 may take the form of any of the embodiments of the coupling components 816 discussed above, and the integrated circuit components 826 and 832 may take the form of any of the embodiments of the integrated circuit component 820 discussed above. The package-on-package structure 834 may be configured in accordance with any of the package-on-package structures known in the art.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 is a method of forming a transistor, comprising: forming a buffer layer on a substrate, the buffer layer comprising a first group III-nitride (III-N) material; forming a channel layer on the buffer layer, the channel layer comprising a second III-N material; forming a polarization layer on the channel layer, the polarization layer comprising a third III-N material; flowing a p-type dopant precursor compound after forming the polarization layer; forming a p-type doped layer on the polarization layer, the p-type doped layer comprising a p-type dopant and a fourth III-N material; forming a source region adjacent one end of the channel layer; and forming a drain region adjacent another end of the channel layer.

Example 2 includes the subject matter of Example 1, wherein the p-type dopant precursor compound comprises magnesium.

Example 3 includes the subject matter of Example 1 or 2, wherein the p-type dopant precursor compound comprises Bis(cyclopentadienyl)magnesium.

Example 4 includes the subject matter of any one of Examples 1-3, wherein the p-type dopant precursor compound is flowed using chemical vapor deposition.

Example 5 includes the subject matter of any one of Examples 1-4, wherein the p-type dopant precursor compound is flowed at a temperature between 900-1050° C., a pressure between 20-500 Torr, and at flow a rate between 0.0005-0.005 mol per minute for at least 2 minutes.

Example 6 includes the subject matter of any one of Examples 1-5, wherein the first III-N material comprises aluminum, gallium, and nitrogen.

Example 7 includes the subject matter of any one of Examples 1-6, wherein the second III-N material comprises gallium, and nitrogen.

Example 8 includes the subject matter of any one of Examples 1-7, wherein the third III-N material comprises aluminum, gallium, and nitrogen.

Example 9 includes the subject matter of any one of Examples 1-8, wherein the fourth III-N material comprises gallium and nitrogen, and the p-type dopant comprises magnesium.

Example 10 includes the subject matter of any one of Examples 1-9, further comprising forming a passivation layer on the polarization layer.

Example 11 includes the subject matter of any one of Examples 1-10, further comprising forming a gate contact on the p-type doped layer.

Example 12 includes the subject matter of any one of Examples 1-11, further comprising forming a source contact on the source region and forming a drain contact on the drain region.

Example 13 includes the subject matter of any one of Examples 1-12, wherein the source region and the drain region each comprise a fifth III-N material.

Example 14 includes the subject matter of Example 13, wherein the fifth III-N material comprises indium, gallium, and nitrogen.

Example 14.5 is a product formed by the process of any one of Examples 1-14.

Example 15 is an apparatus comprising: a substrate; a buffer layer on the substrate, the buffer layer comprising a first group III-nitride (III-N) material; a channel layer on the buffer layer, the channel layer comprising a second III-N material; a polarization layer on the channel layer, the polarization layer comprising a third III-N material; a p-type doped layer on the polarization layer, the p-type doped layer comprising a p-type dopant and a fourth III-N material and having a thickness of less than 20 nm; and a source region adjacent one end of the channel layer; and a drain region adjacent another end of the channel layer

Example 16 includes the subject matter of Example 15, wherein the polarization layer comprises the p-type dopant at a concentration of at least 1×1019 at/cm3 adjacent the p-type doped layer.

Example 17 includes the subject matter of Example 15 or 16, wherein the p-type dopant comprises magnesium.

Example 18 includes the subject matter of any one of Examples 15-17, wherein the first III-N material comprises aluminum, gallium, and nitrogen.

Example 19 includes the subject matter of any one of Examples 15-18, wherein the second III-N material comprises gallium, and nitrogen.

Example 20 includes the subject matter of any one of Examples 15-19, wherein the third III-N material comprises aluminum, gallium, and nitrogen.

Example 21 includes the subject matter of any one of Examples 15-20, wherein the fourth III-N material comprises gallium and nitrogen, and the p-type dopant comprises magnesium.

In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure. However, the order of description should not be construed to imply that these operations are necessarily order dependent. In particular, these operations may not be performed in the order of presentation.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

As used herein, the term “circuitry” may refer to, be part of, or include an Application Specific Integrated Circuit (ASIC), an electronic circuit, a processor (shared, dedicated, or group), and/or memory (shared, dedicated, or group) that execute one or more software or firmware programs, a combinational logic circuit, and/or other suitable hardware components that provide the described functionality. As used herein, “computer-implemented method” may refer to any method executed by one or more processors, a computer system having one or more processors, a mobile device such as a smartphone (which may include one or more processors), a tablet, a laptop computer, a set-top box, a gaming console, and so forth.

1. An apparatus comprising:
a substrate;
a buffer layer on the substrate, the buffer layer comprising a first group III-nitride (III-N) material;
a channel layer on the buffer layer, the channel layer comprising a second III-N material;
a polarization layer on the channel layer, the polarization layer comprising a third III-N material;
a p-type doped layer on the polarization layer, the p-type doped layer comprising a p-type dopant and a fourth III-N material and having a thickness of less than 20 nm; and
a source region adjacent one end of the channel layer; and
a drain region adjacent another end of the channel layer.

2. The apparatus of claim 1, wherein the polarization layer comprises the p-type dopant at a concentration of at least 1×10¹⁹ at/cm³ adjacent the p-type doped layer.

3. The apparatus of claim 1, wherein the p-type dopant comprises magnesium.

4. The apparatus of claim 1, wherein the first III-N material comprises aluminum, gallium, and nitrogen.

5. The apparatus of claim 1, wherein the second III-N material comprises gallium, and nitrogen.

6. The apparatus of claim 1, wherein the third III-N material comprises aluminum, gallium, and nitrogen.

7. The apparatus of claim 1, wherein the fourth III-N material comprises gallium and nitrogen, and the p-type dopant comprises magnesium.

8. The apparatus of claim 1, wherein the source region and the drain region each comprise a fifth III-N material comprising indium, gallium, and nitrogen.

9. A method of forming a transistor, comprising:
forming a buffer layer on a substrate, the buffer layer comprising a first group III-nitride (III-N) material;
forming a channel layer on the buffer layer, the channel layer comprising a second III-N material;
forming a polarization layer on the channel layer, the polarization layer comprising a third III-N material;
flowing a p-type dopant precursor compound after forming the polarization layer;
forming a p-type doped layer on the polarization layer, the p-type doped layer comprising a p-type dopant and a fourth III-N material;
forming a source region adjacent one end of the channel layer; and
forming a drain region adjacent another end of the channel layer.

10. The method of claim 9, wherein the p-type dopant precursor compound comprises magnesium.

11. The method of claim 9, wherein the p-type dopant precursor compound comprises Bis(cyclopentadienyl)magnesium.

12. The method of claim 9, wherein the p-type dopant precursor compound is flowed using chemical vapor deposition.

13. The method of claim 9, wherein the p-type dopant precursor compound is flowed at a temperature between 900-1050° C., a pressure between 20-500 Torr, and at flow a rate between 0.0005-0.005 mol per minute for at least 2 minutes.

14. The method of claim 9, wherein:
the first III-N material comprises aluminum, gallium, and nitrogen;
the second III-N material comprises gallium, and nitrogen;
the third III-N material comprises aluminum, gallium, and nitrogen; and
the fourth III-N material comprises gallium and nitrogen, and the p-type dopant comprises magnesium.

15. The method of claim 9, wherein the source region and drain region are each formed using a fifth III-N material comprising indium, gallium, and nitrogen.

16. A product formed by the process comprising:
forming a buffer layer on a substrate, the buffer layer comprising a first group III-nitride (III-N) material;
forming a channel layer on the buffer layer, the channel layer comprising a second III-N material;
forming a polarization layer on the channel layer, the polarization layer comprising a third III-N material;
flowing a p-type dopant precursor compound after forming the polarization layer;
forming a p-type doped layer on the polarization layer, the p-type doped layer comprising a p-type dopant and a fourth III-N material; and
forming a source region adjacent one end of the channel layer; and
forming a drain region adjacent another end of the channel layer.

17. The product of claim 16, wherein the p-type dopant precursor compound comprises magnesium.

18. The product of claim 16, wherein the p-type dopant precursor compound comprises Bis(cyclopentadienyl)magnesium.

19. The product of claim 16, wherein the p-type dopant precursor compound is flowed using chemical vapor deposition.

20. The product of claim 16, wherein the p-type dopant precursor compound is flowed at a temperature between 900-1050° C., a pressure between 20-500 Torr, and at flow a rate between 0.0005-0.005 mol per minute for at least 2 minutes.
